(19) United States
(12) Patent Application Publication
(10) Pub. No.: US 2025/0246474 A1
(43) Pub. Date: Jul. 31, 2025

(54) SUBSTRATE FIXING DEVICE

(71) Applicant: SHINKO ELECTRIC INDUSTRIES CO., LTD., Nagano-shi (JP)

(72) Inventors: Madoka Yamakami, Nagano (JP); Masahiro Sunohara, Nagano (JP)

(21) Appl. No.: 19/039,442

(22) Filed: Jan. 28, 2025

(30) Foreign Application Priority Data
Jan. 30, 2024 (JP) 2024-012096

(51) Int. Cl. H01L 21/683; H01L 21/67; H01L 21/687

(52) U.S. Cl. CPC H01L 21/6833; H01L 21/67103; H01L 21/68757

(57) ABSTRACT

A substrate fixing device includes a base plate, a first adhesive layer, and an electrostatic chuck mounted on the base plate via the first adhesive layer. The electrostatic chuck includes a first base body made of a ceramic material as a main component, a second adhesive layer, a second base body having a placement surface for mounting a target object to be adsorbed, disposed on the first base body via the second adhesive layer, and made of a ceramic material as a main component, and an electrostatic electrode built in the second base body, and the first base body is disposed on the first adhesive layer.

### CROSS-REFERENCE TO RELATED APPLICATIONS

This application claims priority from Japanese Patent Application No. 2024-012096 filed on Jan. 30, 2024, the contents of which are incorporated herein by reference.

### TECHNICAL FIELD

The present invention relates to a substrate fixing device.

### BACKGROUND ART

In the related art, a film formation apparatus and a plasma etching apparatus, which are used when manufacturing a semiconductor device, each have a stage for accurately holding a wafer in a vacuum treatment chamber. As such a stage, for example, a substrate fixing device is suggested which adsorbs and holds a wafer by an electrostatic chuck mounted on a base plate.

Such a substrate fixing device has a structure in which, for example, a second base body made of ceramic and having a built-in electrode is directly bonded on a first base body made of ceramic and having a built-in heater. An upper surface of the second base body serves as a placement surface for placing a target object to be adsorbed such as a wafer (see, for example, Patent Literature 1).

### CITATION LIST

### Patent Literature

PTL 1: JP2022-123983A

### SUMMARY OF INVENTION

The substrate fixing device is used in a plasma environment. In this case, the second base body with a placement surface may be exposed to plasma and deteriorate. However, in the structure in which two base bodies made of ceramic are directly bonded, such as the above, it is difficult to replace only the second base body even when the second base body deteriorates. On the other hand, when the second base body deteriorates, if a part other than the second base body, such as the first base body, is also replaced, the cost burden increases.

An object of the present disclosure is to facilitate replacement of a second base body in a substrate fixing device in which the second base body with a placement surface is arranged on a first base body.

According to one aspect of the present disclosure, a substrate fixing device includes
a base plate;
a first adhesive layer; and
an electrostatic chuck mounted on the base plate via the first adhesive layer, wherein
the electrostatic chuck includes:
   a first base body made of a ceramic material as a main component,
   a second adhesive layer,
   a second base body having a placement surface for mounting a target object to be adsorbed, disposed on the first base body via the second adhesive layer, and made of a ceramic material as a main component, and
   an electrostatic electrode built in the second base body, and
the first base body is disposed on the first adhesive layer.

According to the technology of the disclosure, it is possible to facilitate replacement

of a second base body in a substrate fixing device in which the second base body with a placement surface is arranged on a first base body.

### BRIEF DESCRIPTION OF DRAWINGS

FIG. 1 is a simplified cross-sectional view illustrating a substrate fixing device according to a first embodiment.

FIGS. 2A to 2C are views illustrating a manufacturing process of a substrate fixing device according to the first embodiment.

FIGS. 3A to 3C are views illustrating the manufacturing process of a substrate fixing device according to the first embodiment.

FIG. 4 is a simplified cross-sectional view illustrating a substrate fixing device according to Variation 1 of the first embodiment.

FIG. 5 is a simplified cross-sectional view illustrating a substrate fixing device according to Variation 2 of the first embodiment.

### DESCRIPTION OF EMBODIMENTS

Hereinafter, embodiments of the present invention will be described with reference to the drawings. Note that, in the respective drawings, the parts having the same configurations are denoted with the same reference signs, and the redundant descriptions may be omitted.

### First Embodiment

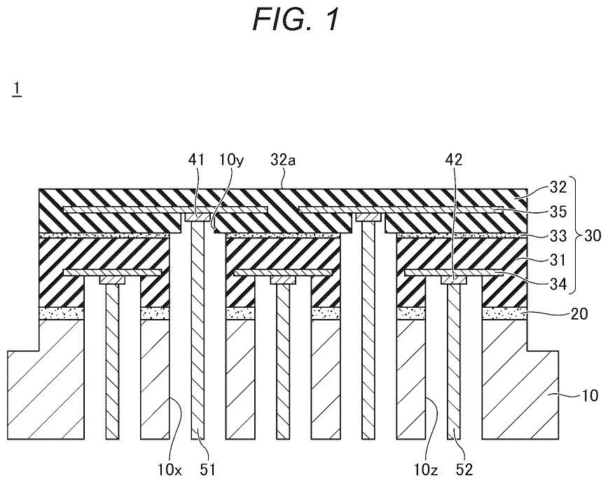

FIG. 1 is a simplified cross-sectional view illustrating a substrate fixing device according to a first embodiment. Referring to FIG. 1, a substrate fixing device 1 includes, as main constituent elements, a base plate 10, a first adhesive layer 20, and an electrostatic chuck 30. The substrate fixing device 1 is a device that adsorbs and holds a substrate (a wafer or the like), which is a target object to be adsorbed, by the electrostatic chuck 30 mounted on one surface of the base plate 10.

The base plate 10 is a member for mounting the electrostatic chuck 30. A thickness of the base plate 10 is, for example, about 20 to 50 mm. The base plate 10 may be formed of, for example, metal such as aluminum, copper, or titanium. Among them, aluminum is preferably used which is inexpensive and easy to process.

The base plate 10 may also be used as an electrode for controlling plasma, or the like. By supplying predetermined high-frequency electric power to the base plate 10, the energy for causing ions and the like in a generated plasma state to collide with a wafer adsorbed on the electrostatic chuck 30 can be controlled to effectively perform etching processing.

A flow channel may be provided inside the base plate 10. In this case, the flow channel is connected to a cooling medium control device provided outside the substrate fixing device 1, and the cooling medium control device introduces and discharges a cooling medium into the flow channel. By circulating the cooling medium through the flow channel using the cooling medium control device to cool the base plate 10, the wafer adsorbed on the electrostatic chuck 30 can be cooled. As the cooling medium, for example, water or Galden may be used. In addition to the flow channel, a gas channel for introducing an inert gas to cool the wafer adsorbed on the electrostatic chuck 30, or the like may be provided in the base plate 10.

The electrostatic chuck 30 is mounted on the base plate 10 with the first adhesive layer 20 interposed therebetween. As the first adhesive layer 20, for example, a silicone-based resin may be used. As the first adhesive layer 20, an epoxy-based resin or an acrylic resin may be used. As the first adhesive layer 20, an inorganic material may also be used. A thickness of the first adhesive layer 20 is preferably thick. The thickness of the first adhesive layer 20 may be, for example, about 0.2 to 1.5 mm. By setting the first adhesive layer 20 to this thickness, it is possible to reduce stress resulting from a difference in thermal expansion rates between the electrostatic chuck 30 made of ceramic and the base plate 10 made of aluminum.

The thermal conductivity of the first adhesive layer 20 is preferably 2 W/mK or higher. The first adhesive layer 20 may be formed as a single layer, but may also have a two-layer structure combining an adhesive with high thermal conductivity and an adhesive with low elasticity. This can further reduce the stress resulting from the difference in thermal expansion rates between the electrostatic chuck 30 made of ceramic and the base plate 10 made of aluminum.

The electrostatic chuck 30 is a part that adsorbs and holds a wafer, which is a target object to be adsorbed. A planar shape of the electrostatic chuck 30 may be circular, for example. A diameter of the wafer, which is a target object to be adsorbed of the electrostatic chuck 30, may be, for example, about 8 inches, 12 inches or 18 inches. The electrostatic chuck 30 is, for example, a Coulomb force-type electrostatic chuck. However, the electrostatic chuck 30 may also be a Johnson-Rahbek-type electrostatic chuck.

The electrostatic chuck 30 includes a first base body 31, a second base body 32, and a second adhesive layer 33. The first base body 31 is disposed on the first adhesive layer 20. The second base body 32 is disposed on the first base body 31 via the second adhesive layer 33. That is, the first base body 31 and the second base body 32 are disposed with the second adhesive layer 33 interposed therebetween.

The first base body 31 is a dielectric whose main component is a ceramic material. The first base body 31 may, for example, have aluminum oxide as its main component. Here, the main component is a component that accounts for 90 wt % or more of components included in a target area. Note that the first base body 31 may have a ceramic material other than aluminum oxide, as its main component. Examples of the ceramic material other than aluminum oxide include mullite. A thickness of the base layer 31 is, for example, about 2 to 10 mm.

The first base body 31 may, for example, have a built-in heating element 34. The heating element 34 generates heat by applying a voltage from the outside of the substrate fixing device 1, and heats a placement surface 32a (described below) of the second base body 32 to a predetermined temperature. The heating element 34 can heat, for example, the placement surface 32a of the second base element 32 to the temperature of about 250° C. to 300° C. As the material of the heating element 34, for example, tungsten (W), molybdenum (Mo), or the like may be used. The heating element 34 may be formed in a concentric circle pattern, for example. A thickness of the heating element 34 is, for example, about 10 to 50 μm. Note that the first base body 31 may have a built-in conductor other than the heating element 34.

The second base body 32 has a placement surface 32a for mounting a target object to be adsorbed. A surface of the second base body 32 on an opposite side to the second adhesive layer 33 is the placement surface 32a. The second base body 32 is a dielectric whose main component is a ceramic material. The second base body 32 may, for example, have aluminum oxide as its main component. In the second base body 32, the purity of aluminum oxide is, for example, 90 wt % or more and 97 wt % or less. A thickness of the second base layer 32 is, for example, about 1 to 5 mm. A relative permittivity (1 MHz) of the second base body 32 is, for example, about 7 to 10.

The second base body 32 and the first base body 31 preferably have the same ceramic material as their main component. The second base body 32 and the first base body 31 may, for example, have aluminum oxide as their main component. By configuring the second base body 32 and the first base body 31 with the same ceramic material as their main component, the physical property values (for example, thermal expansion coefficient) of the second base body 32 and the first base body 31 can be made closer to each other. As a result, the occurrence of warping caused by heat can be prevented.

The second base body 32 has a built-in electrostatic electrode 35. The electrostatic electrode 35 is, for example, a thin film electrode. The electrostatic electrode 35 is connected to a power supply provided outside the substrate fixing device 1, and generates adsorption force between the electrostatic electrode and the wafer by static electricity when a predetermined voltage is applied from the power supply. This enables the wafer to be adsorbed and held on the placement surface 32a of the second base body 32. The electrostatic electrode 35 may have a unipolar shape or a bipolar shape. As a material of the electrostatic electrode 35, tungsten, molybdenum or the like may be used, for example.

The adsorption holding force between the electrostatic electrode 35 and the target object to be adsorbed becomes stronger as the voltage applied to the electrostatic electrode 35 is higher, and also becomes stronger as the relative permittivity of the second base body 32 is higher. Since there is a limit to increasing the voltage applied to the electrostatic electrode 35, it can be considered that a higher relative permittivity of the second base body 32 is more preferable in terms of the adsorption holding force. In this respect, to secure a certain level of adsorption holding force, the second base body 32 preferably has aluminum oxide, which has a high relative permittivity among ceramics, as its main component.

As the second adhesive layer 33, for example, a silicone-based resin may be used. As the second adhesive layer 33, an epoxy-based resin or an acrylic resin may be used. As the second adhesive layer 33, an inorganic material may also be used. For the second adhesive layer 33, the same material as the first adhesive layer 20, or a different material, may be used.

The second adhesive layer 33 may be thinner than the first adhesive layer 20. This is because the upper and lower sides of the second adhesive layer 33 are both the base bodies made of ceramic as the main component, and the difference in thermal expansion coefficient is small or the thermal expansion coefficients are substantially the same, so there is no need to provide the effect of reducing stress by increasing the thickness. A thickness of the first adhesive layer 33 may be, for example, about 0.05 to 0.2 mm.

The substrate fixing device 1 may have a first hole 10x and a second hole 10y communicating with the first hole 10x. The first hole 10x may be provided to continuously penetrate through the base plate 10, the first adhesive layer 20, the first base body 31, and the second adhesive layer 33, and to expose a lower surface of the second base body 32. The second hole 10y may be provided in the second base body 32 to expose a lower surface of the electrostatic electrode 35.

The second hole 10y is smaller than the first hole 10x in a bottom view of the base plate 10. The first hole 10x may be formed into a circular shape, for example, in a bottom view of the base plate 10. The second hole 10y mad be formed into a circular shape with a smaller diameter than, for example, the first hole 10x, in a bottom view of the base plate 10. In this case, the diameter of the first hole 10x is, for example, about 2.5 to 4.0 mm, and the diameter of the second hole 10y is, for example, about 1.0 to 2.0 mm.

The substrate fixing device 1 may have a third hole 10z. The third hole 10z may be provided to continuously penetrate through the base plate 10, the first adhesive layer 20, and the first base body 31 and to expose a lower surface of the heating body 34. The third hole 10z may be formed into a circular shape, for example, in a bottom view of the base plate 10. The third hole 10z may be formed into a circular shape with the same diameter as that of the first hole 10x, for example, in a bottom view of the base plate 10.

The substrate fixing device 1 may have a power feeding terminal 51 electrically connected to the lower surface of the electrostatic electrode 35 exposed within the second hole 10y. The power feeding terminal 51 may be inserted into, for example, the first hole 10x and the second hole 10y, and electrically connected to the lower surface of the electrostatic electrode 35 via a solder 41.

The substrate fixing device 1 may have a power feeding terminal 52 electrically connected to the lower surface of the heating element 34 exposed within the third hole 10z. The power feeding terminal 52 may be inserted into, for example, the third hole 10z and electrically connected to the lower surface of the heating element 34 via a solder 42.

As the power feeding terminals 51 and 52, pins or wires may be used, for example. For the material of the power feeding terminals 51 and 52, for example, metal such as Kovar may be used. The power feeding terminals 51 and 52 may extend from the lower surface of the base plate 10. For the bonding of the power feeding terminals 51 and 52, a brazing material may be used instead of the solders 41 and 42. By providing the power feeding terminals 51 and 52, power can be easily fed to the electrostatic electrode 35 and the heating element 34 from the outside of the substrate fixing device 1.

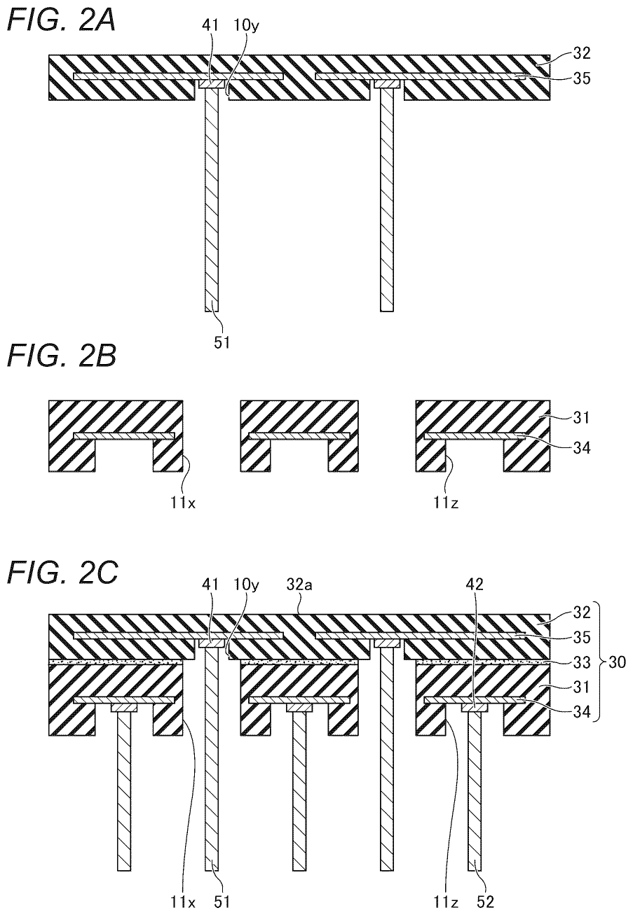

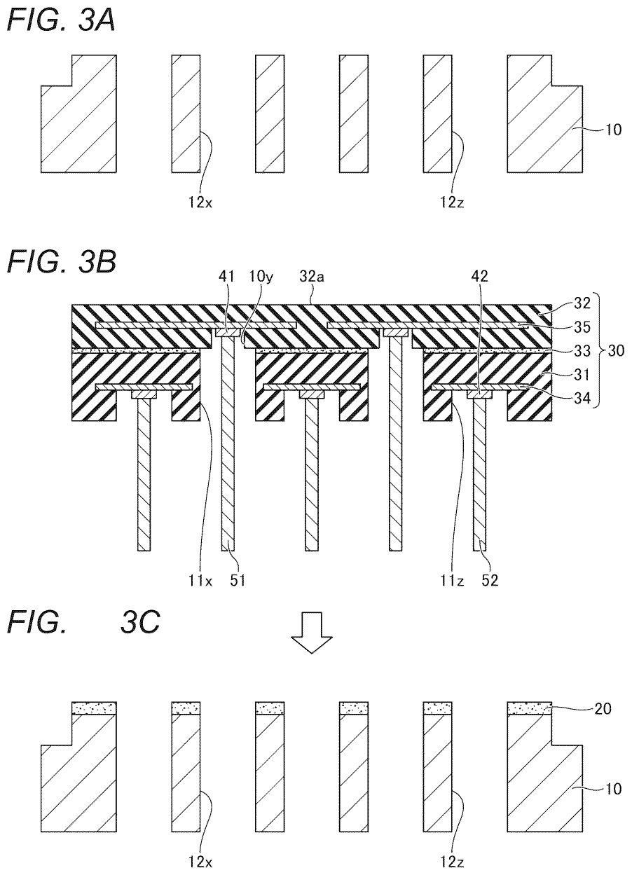

FIGS. 2A to 3C are views illustrating a manufacturing process of a substrate fixing device according to the first embodiment. First, in a process shown in FIG. 2A, a second base body 32 having a built-in electrostatic electrode 35 is formed, and a second hole 10y is formed at a necessary location. Then, a power feeding terminal 51 is electrically connected to a lower surface of the electrostatic electrode 35 exposed within the second hole 10y, via a solder 41. Note that a first base body 31 and the electrostatic electrode 35 may be manufactured by a known manufacturing method including, for example, a process of forming a pattern to become the electrostatic electrode 35 on a first green sheet, a process of stacking and firing a second green sheet on the first green sheet, a process of flattening a surface, and the like.

Next, in a process shown in FIG. 2B, a first base body 31 having a built-in heating element 34 is formed, and a first hole 11x and a third hole 11z are formed at necessary locations. The first hole 11x is formed larger than the second hole 10y shown in FIG. 2A. Note that the second base body 32 and the heating body 34 may be manufactured by, for example, a method similar to that for the first base body 31 and the electrostatic electrode 35.

Next, in a process shown in FIG. 2C, an uncured second adhesive layer 33 is arranged in an area, in which the first hole 11x and the third hole 11z are not formed, on the first base body 31 manufactured in the process shown in FIG. 2B. Then, the second base body 32 manufactured in the process shown in FIG. 2A is positionally aligned relative to the first base body 31 on the uncured second adhesive layer 33, and the second adhesive layer 33 is cured. At this time, the first hole 11x is formed larger than the second hole 10y, allowing for a certain degree of positional misalignment. Therefore, positional alignment between the first hole 11x and the second hole 10y is easily achieved. After the second adhesive layer 33 is cured, a power feeding terminal 52 is electrically connected to the lower surface of the heating element 34 exposed within the third hole 11z, via a solder 42. With this, an electrostatic chuck 30 is completed.

Next, in a process shown in FIG. 3A, a base plate 10 having a first hole 12x and a third hole 12z formed therein is prepared. The first hole 12x and the third hole 12z are formed at positions corresponding to the first hole 11x and the third hole 11z shown in FIG. 2C and to have sizes corresponding to those holes.

Next, in a process shown in FIG. 3B, an uncured first adhesive layer 20 is arranged in an area on the base plate 10 where the first hole 12x and the third hole 12z are not formed. Then, the electrostatic chuck 30 is arranged on the uncured first adhesive layer 20, and the first adhesive layer 20 is cured. The first hole 11x communicates with the first hole 12x and becomes the first hole 10x as shown in FIG. 1. In addition, the third hole 11z communicates with the third hole 12z and becomes the third hole 10z shown in FIG. 1. As a result, a substrate fixing device 1 is completed.

In this way, in the substrate fixing device 1, the electrostatic chuck 30 includes the first base body 31, the second base body 32 having the built-in electrostatic electrode 35, and the second adhesive layer 33 adhering the first base body and the second base body. With this structure, the replacement of the second base body 32 can be facilitated. That is, the deteriorated second base body 32 can be separated from the first base body 31 and discarded, and replaced with an undeteriorated second base body 32. In this case, the base plate 10 or first base body 31 can be used as is, resulting in cost reduction.

In addition, even when the second base body 32 is not deteriorated, it may be desired to change the specifications of the second base body 32, such as changing the pattern of the electrostatic electrode 35. In this case, the second base body 32 with old specifications can be separated from the first base body 31 and discarded, and replaced with a second base body 32 with new specifications. In this case, the base plate 10 or first base body 31 can be commonly used as general-purpose components, resulting in cost reduction.

In addition, for example, when the main components of the first base body 31 and the second base body 32 are aluminum oxide, increasing the purity of the aluminum oxide can improve the plasma resistance. For this reason, the second base body 32, which is inherently exposed to plasma and deteriorates, should desirably have a higher purity of aluminum oxide than the first base body 31. However, increasing the purity of the aluminum oxide leads to an increase in cost. Therefore, in the substrate fixing device 1 in which the second base body 32 can be replaced, the purity of the aluminum oxide of the second base body 32 may be made to be equal to or lower than the purity of the aluminum oxide of the first base body 31. With this, it is possible to suppress the cost of the second base body 32.

In addition, if a heating element and an electrostatic electrode are built into a single base body, it is difficult to optimize a distance between the two because they cannot be spaced far apart from each other. In the structure in which the first base body 31 and the second base body 32 are bonded together, as in the substrate fixing device 1, the degree of design freedom is increased, and the distance between the heating body 34 and the electrostatic electrode 35 can be optimized. As a result, temperature control by the heating element 34 becomes easier. Note that, in order to separate the second base body 32 from the first base body 31,

for example, a blade or the like may be prepared and a portion of the second adhesive layer 33 may be cut by the blade or the like. Polishing or grinding may be performed as needed. From the perspective of facilitating cutting of the second adhesive layer 33, the second adhesive layer 33 is preferably formed of a relatively flexible organic material, such as a silicone-based resin, rather than an inorganic material.

### Variation 1 of First Embodiment

Variation 1 of the first embodiment shows an example of a substrate fixing device having a sleeve. Note that, in Variation 1 of the first embodiment, the descriptions of the same constitutional parts as the embodiment already described may be omitted.

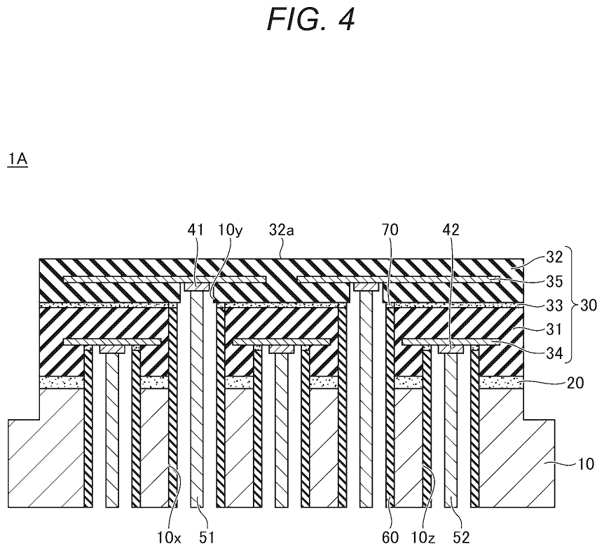

FIG. 4 is a simplified cross-sectional view illustrating a substrate fixing device according to Variation 1 of the first embodiment. Referring to FIG. 4, a substrate fixing device 1A is different from the substrate fixing device 1 in that it has a sleeve 60.

The sleeve 60 is a tubular insulating member. The sleeve 60 is, for example, in the shape of a hollow cylinder. On an inner inside of the sleeve 60, the power feeding terminal 51 electrically connected to the lower surface of the electrostatic electrode 35 exposed within the second hole 10y is arranged. In addition, on an inner side of another sleeve 60, the power feeding terminal 52 electrically connected to the lower surface of the heating element 34 exposed within the third hole 10z is arranged. In the case that the diameter of the first hole 10x is, for example, about 2.5 to 4.0 mm, and the diameter of the second hole 10y is, for example, about 1.0 to 2.0 mm, a thickness of the sleeve 60 is, for example, about 0.5 to 2.0 mm.

A material of the sleeve 60 is an inorganic insulator such as aluminum oxide, for example. The material of the sleeve 60 may also be an organic insulator such as polyimide. Since the base plate 10 is formed of a conductive material such as aluminum, discharge may occur from the power feeding terminal 51 and/or 52 toward the base plate 10. By providing the sleeve 60, the discharge can be suppressed.

In the substrate fixing device 1A, the sleeve 60 extends from the inner side of the first hole 10x located in the base plate 10 to the inner side of the first hole 10x located in the first adhesive layer 20, the first base body 31, and the second adhesive layer 33. An end portion of the sleeve 60 is adhered to the lower surface of the second base body 32 exposed around the second hole 10y, via an adhesive 70. In addition, in the substrate fixing device 1A, the sleeve 60 extends from the inner side of the third hole 10z located in the base plate 10 to the inner side of the third hole 10z located in the first adhesive layer 20 and the first base body 31. An end portion of the sleeve 60 is adhered to the lower surface of the heating element 34 exposed within the third hole 10z, via the adhesive 70. As the adhesive 70, for example, an epoxy-based resin may be used.

Note that from the perspective of suppressing discharge, the sleeve 60 is preferably arranged on the inner side of the first hole 10x and the third hole 10z located at least in the base plate 10. The sleeve 60 may be, for example, pressed into the inner side of the first hole 10x and the third hole 10z located in the base plate 10.

### Variation 2 of First Embodiment

Variation 2 of the first embodiment shows an example of a substrate fixing device having a heating element different from that of the first embodiment. Note that, in Variation 2 of the first embodiment, the descriptions of the same constitutional parts as the embodiment already described may be omitted.

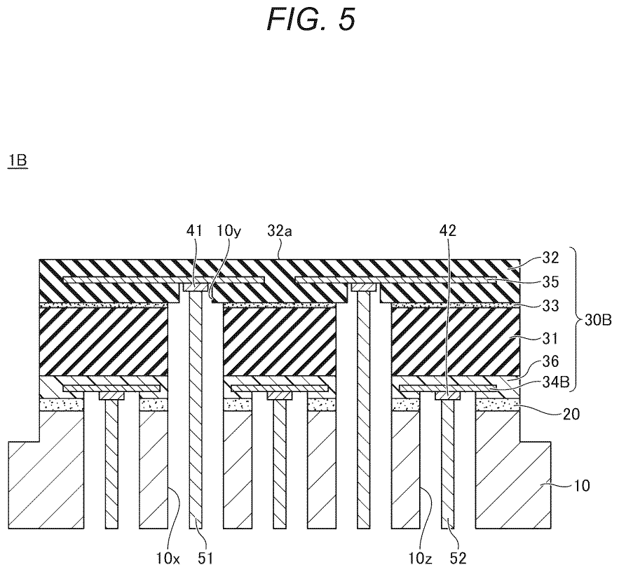

FIG. 5 is a simplified cross-sectional view illustrating a substrate fixing device according to Variation 2 of the first embodiment. Referring to FIG. 5, a substrate holding device 1B is different from the substrate holding device 1 in that the electrostatic chuck 30 is replaced with an electrostatic chuck 30B.

In the electrostatic chuck 30B, the heating element 34 is not built in the first base body 31. The first base body 31 may be used, for example, for thickness adjustment of the electrostatic chuck 30B. Alternatively, a conductor other than a heating element may be built in the first base body 31. The electrostatic chuck 30B includes an insulating resin layer 36 arranged between the first adhesive layer 20 and the first base body 31, and the insulating resin layer 36 has a built-in heating element 34B. The heating element 34B and the insulating resin layer 36 are a so-called laminate heater.

As the insulating resin layer 36, for example, an epoxy-based resin, a bismaleimide triazine-based resin, or the like having high thermal conductivity and high heat resistance may be used. The thermal conductivity of the insulating resin layer 36 is preferably 3 W/mK or higher. The insulating resin layer 36 may contain a filler such as aluminum oxide or aluminum nitride. With this, the thermal conductivity of the insulating resin layer 36 can be improved. Additionally, the glass transition temperature (Tg) of the insulating resin layer 36 is preferably 250° C. or higher. In addition, a thickness of the insulating resin layer 36 is preferably about 100 to 150 μm, and a thickness variation of the insulating resin layer 36 is preferably ±10% or less.

As materials for the heating element 34B, for example, copper (Cu), tungsten (W), nickel (Ni), aluminum (Al), constantan (an alloy of Cu/Ni/Mn/Fe), Zeranin (an alloy of Cu/Mn/Sn), Manganin (an alloy of Cu/Mn/Ni), or the like may be used. The heating element 34B may be formed in a concentric circle pattern, for example.

In this way, a structure may be adopted in which the heating element 34B is built in the insulating resin layer 36 arranged between the first adhesive layer 20 and the first base body 31, rather than embedding the heating element in the first base body 31.

Although the preferred embodiments and the like have been described in detail, the present invention is not limited to the above-described embodiments and the like, and a variety of changes and replacements can be made for the above-described embodiments and the like without departing from the scope defined in the claims.

For example, as a target object to be adsorbed of the substrate fixing device according to the present invention, a glass substrate used in a manufacturing process of a liquid crystal panel, and the like may be exemplified, in addition to a wafer (such as a silicon wafer).

What is claimed is:

1. A substrate fixing device, comprising:
a base plate;
a first adhesive layer; and
an electrostatic chuck mounted on the base plate via the first adhesive layer, wherein
the electrostatic chuck comprises:
a first base body made of a ceramic material as a main component,
a second adhesive layer,
a second base body having a placement surface for mounting a target object to be adsorbed, disposed on the first base body via the second adhesive layer, and made of a ceramic material as a main component, and
an electrostatic electrode built in the second base body, and
the first base body is disposed on the first adhesive layer.

2. The substrate fixing device according to claim 1, comprising:
a first hole provided to continuously penetrate through the base plate, the first adhesive layer, the first base body, and the second adhesive layer and expose a lower surface of the second base body, and
a second hole provided in the second base body so as to communicate with the first hole and to expose a lower surface of the electrostatic electrode, wherein
the second hole is smaller than the first hole in a bottom view.

3. The substrate fixing device according to claim 2, comprising:
a tubular insulating member arranged on an inner side of the first hole located in the base plate.

4. The substrate fixing device according to claim 3, wherein the insulating member extends inwardly of the first hole located in the first adhesive layer, the first base body, and the second adhesive layer, and comprises an end portion adhered to a lower surface of the second base body exposed around the second hole.

5. The substrate fixing device according to claim 4, comprising:
a power feeding terminal arranged on an inner side of the insulating member and electrically connected to a lower surface of the electrostatic electrode exposed within the second hole.

6. The substrate fixing device according to claim 1, wherein the second adhesive layer is thinner than the first adhesive layer.

7. The substrate fixing device according to claim 1, wherein the second base body and the first base body have the same ceramic material as a main component.

8. The substrate fixing device according to claim 1, wherein the second adhesive layer is formed of an organic material.

9. The substrate fixing device according to claim 1, wherein the first base body has a built-in heating element.

10. The substrate fixing device according to claim 1, comprising:
an insulating resin layer arranged between the first adhesive layer and the first base body, wherein
the insulating resin layer has a built-in heating element.
